(19) United States
(12) Patent Application Publication
(10) Pub. No.: US 2015/0034901 A1
(43) Pub. Date: Feb. 5, 2015

(54) SEMICONDUCTOR LIGHT EMITTING ELEMENT

(71) Applicants: Kyoto University, Kyoto-shi, Kyoto (JP); HAMAMATSU PHOTONICS K.K., Hamamatsu-shi, Shizuoka (JP)

(72) Inventors: Susumu Noda, Kyoto-shi (JP); Yoshitaka Kurosaka, Hamamatsu-shi (JP); Akiyoshi Watanabe, Hamamatsu-shi (JP); Kazuyoshi Hirose, Hamamatsu-shi (JP); Takahiro Sugiyama, Hamamatsu-shi (JP)

(73) Assignees: Kyoto University, Kyoto-shi, Kyoto (JP); HAMAMATSU PHOTONICS K.K., Hamamatsu-shi, Shizuoka (JP)

(21) Appl. No.: 14/373,967

(22) PCT Filed: Nov. 7, 2012
(86) PCT No.: PCT/JP2012/078869

§ 371 Date: Jul. 23, 2014

(30) Foreign Application Priority Data
Feb. 6, 2012 (JP) 2012-023129

(51) Int. Cl. H01L 33/10

(52) U.S. Cl. CPC H01L 33/105; H01L 2933/0083
USPC 257/13

(57) ABSTRACT

A semiconductor light emitting element includes an electrode 8, an active layer 3, a photonic crystal layer 4, and an electrode 9. Conductivity types between the active layer 3 and the electrode 8 and between the active layer 3 and the electrode 9 differ from each other. The electrode 8, the active layer 3, the photonic crystal layer 4, and the electrode 9 are stacked along the X-axis. The X-axis passes through a central part 8a2 of the opening 8a when viewed from the axis line direction of the X-axis. The end 9e1 of the electrode 9 and the end 8e1 of the opening 8a substantially coincide with each other when viewed from the axis line direction of the X-axis.

### TECHNICAL FIELD

The present invention relates to a semiconductor light emitting element.

### BACKGROUND ART

In Patent Literature 1, a surface-emitting laser light source having a two-dimensional photonic crystal structure is disclosed. The surface-emitting laser light source of Patent Literature 1 includes a window-shaped electrode to which an opening having no electrode material is provided, an active layer, and a rectangular-shaped back-surface electrode having an area smaller than that of the opening of the window-shaped electrode. The window-shaped electrode is provided on a light emission side of an element substrate. The back-surface electrode is provided on a mounting surface on the side opposite to the window-shaped electrode. An electric current is supplied from the window-shaped electrode and the back-surface electrode to the active layer. The distance between the back-surface electrode and the active layer is smaller than the distance between the element substrate and the active layer, and the range of the current injected into the active layer corresponds to the size of the back-surface electrode.

### CITATION LIST

### Patent Literature

Patent Literature 1: WO 2007/029538

### Non Patent Literature

Non Patent Literature 1: Hirose et al., Effects of Non-lasing Band in Two-Dimensional Photonic Crystal Lasers, Proceedings of the 59th Meeting of the Japan Society of Applied Physics and Related Societies

### SUMMARY OF INVENTION

### Technical Problems

The inventors of the present invention have found that a very weak noise pattern exists at the periphery of a light beam emitted in the surface normal direction in the semiconductor light emitting element having a two-dimensional photonic crystal structure as described above (Non Patent Literature 1). This noise pattern is generated because the light in an oscillating state is subjected to inelastic scattering due to, for example, disturbance in the photonic crystals, and is diffracted by the photonic crystals. As a result of studying on the semiconductor light emitting element in which the noise pattern is generated, the inventors have found that the light corresponding to the noise pattern (hereinafter called the noise light) leaks out of the current injection area, that is, into an area in which the emission of light does not occur. The noise light is a problem because, if, for example, an optical interconnection is formed on multiple channels, the optical interconnection can cause crosstalk to adjacent channels. It is inferred that the light generated at the periphery of the back-surface electrode is the noise light, and there is also a problem that the emitted noise light increases when the area of the opening is larger than the area of the back-surface electrode as in the case of Patent Literature 1, and an optical output is not sufficiently obtained when, conversely, the area of the back-surface electrode is larger than the area of the opening.

An object of the present invention, which has been made in view of the above described problems, is to provide a semiconductor light emitting element that can, for example, sufficiently obtain the optical output and reduce the emission of the noise light caused by the photonic crystals.

### Solution to Problems

A semiconductor light emitting element according to one aspect of the present invention includes a first electrode, a semiconductor unit of group III-V compound semiconductors, and a second electrode. The semiconductor unit is provided between the first electrode and the second electrode. The semiconductor unit includes an active layer and a photonic crystal layer. The photonic crystal layer is provided in either of positions between the active layer and the first electrode, and between the active layer and the second electrode. Conductivity types between the active layer and the first electrode and between the active layer and the second electrode differ from each other. The first electrode is provided with an opening. The first electrode, the active layer, the photonic crystal layer, and the second electrode are stacked along a reference axis. The reference axis passes through a central part of the opening when viewed from an axis line direction of the reference axis. The second electrode includes a first end positioned in a first direction when viewed from the axis line direction of the reference axis, and a second end positioned in a second direction that is a direction opposite to the first direction. The opening has a third end positioned in the first direction when viewed from the axis line direction of the reference axis, and a fourth end positioned in the second direction. The first end of the second electrode and the third end of the opening substantially coincide with each other when viewed from the axis line direction of the reference axis.

With this semiconductor light emitting element, the end of the second electrode and the end of the opening substantially coincide with each other when viewed from the axis line direction of the reference axis. As a result, only the noise light near the outer circumference of the opening is blocked by the first electrode. Hence, the optical output can sufficiently be obtained, and the emission of the noise light caused by the photonic crystals can be reduced.

A semiconductor light emitting element according to another aspect of the present invention includes a first electrode, a semiconductor unit of group III-V compound semiconductors, and a second electrode. The semiconductor unit is provided between the first electrode and the second electrode. The semiconductor unit includes an active layer and a photonic crystal layer. The photonic crystal layer is provided in either of positions between the active layer and the first electrode, and between the active layer and the second electrode; conductivity types between the active layer and the first electrode and between the active layer and the second electrode differing from each other; the first electrode including an opening. A minimum value of an intensity of light that is output from the active layer and the photonic crystal layer and reaches the opening is not less than A % (satisfying 10≦A≦30) of a maximum value of the intensity of the light that is output from the active layer and the photonic crystal layer and reaches the opening.

With this semiconductor light emitting element, the weak noise light existing at the outer circumference of the opening does not pass through the opening. As a result, the optical output can sufficiently be obtained, and the emission of the noise light caused by the photonic crystals can be reduced because only the noise light at the outer circumference of the opening is suppressed.

In the semiconductor light emitting element according to another aspect of the present invention, a transmission light intensity of the first electrode decreases as a distance from the outer circumference of the opening increases. As a result, the emission of the noise light caused by the photonic crystals can be reduced because the transmission light intensity of the noise light at the outer edge portion of the opening can be reduced. Occurrence of side lobes generated by a rapid change in the light intensity can be suppressed.

The semiconductor light emitting element according to another aspect of the present invention includes a distributed Bragg reflector (DBR) layer. The DBR layer may be provided on the reference axis, and is provided in either of positions between the first electrode and the photonic crystal layer, and between the second electrode and the photonic crystal layer. By the DBR layer provided in this manner, the intensity of emitted light can be varied between the reference axis direction and other directions. While an intended optical output is emitted along the reference axis direction, the noise light is emitted in directions departing from the reference axis, whereby the emission of the noise light in directions other than the reference axis direction can be reduced.

The semiconductor light emitting element according to another aspect of the present invention includes a first DBR layer and a second DBR layer. The first DBR is provided between the first electrode and the photonic crystal layer, and the second DBR layer is provided between the second electrode and the photonic crystal layer. Consequently, by the DBR layers provided, the intensity of emitted light can be varied between the reference axis direction and other directions. While the intended optical output is emitted along the reference axis direction, the noise light is emitted in directions departing from the reference axis, whereby the emission of the noise light in directions other than the reference axis direction can be reduced.

### Advantageous Effects of Invention

A semiconductor light emitting element according to one aspect of the present invention can, for example, sufficiently obtain the optical output and reduce the emission of the noise light caused by the photonic crystals.

### BRIEF DESCRIPTION OF DRAWINGS

FIG. 1 is a diagram illustrating a semiconductor light emitting element according to a first embodiment of the present invention.

FIG. 2 is a diagram illustrating the semiconductor light emitting element according to the first embodiment.

FIG. 3 is a diagram illustrating the semiconductor light emitting element according to the first embodiment.

FIG. 4 is a graph illustrating a relation between passing intensity of light passing through an opening and a position of an electrode, in the semiconductor light emitting element according to the first embodiment.

FIGS. 5A to 5I are diagrams illustrating a method of manufacturing the semiconductor light emitting element.

FIGS. 6J to 6M are diagrams illustrating the method of manufacturing the semiconductor light emitting element.

FIG. 7 is a diagram illustrating a semiconductor light emitting element according to a second embodiment of the present invention.

FIG. 8 is a diagram explaining a state of light reflection in the semiconductor light emitting element according to the second embodiment.

FIGS. 9A to 9E are diagrams explaining reflection characteristics of light corresponding to incident angles of the light of the semiconductor light emitting element according to the second embodiment.

FIG. 10 is a diagram illustrating a semiconductor light emitting element according to a third embodiment of the present invention.

FIGS. 11A to 11E are diagrams explaining transmission characteristics of light corresponding to incident angles of the light of the semiconductor light emitting element according to the third embodiment.

### DESCRIPTION OF EMBODIMENTS

Embodiments of a semiconductor light emitting element according to one aspect of the present invention will be described below in detail, with reference to the accompanying drawings. The same reference signs will be given to the same elements, and duplicate description thereof will be omitted.

### First Embodiment

A semiconductor light emitting element 10 according to a first embodiment of the present invention is what is called an end-face-emitting photonic crystal laser element. When an XYZ orthogonal coordinate system is set, the X-axis is set in the element thickness direction, and the Y-axis and the Z-axis are set in directions orthogonal to the X-axis, a laser beam emitting surface is positioned parallel to the YZ-plane. The X-axis corresponds to a reference axis. A laser beam LA is emitted along the X-axis direction from the semiconductor light emitting element 10.

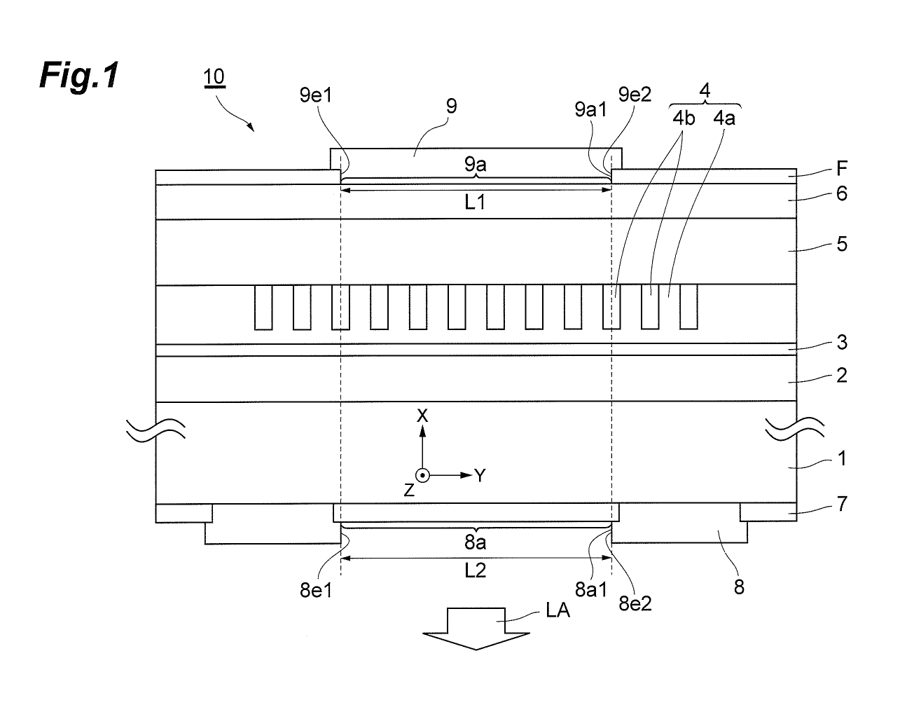

As illustrated in FIG. 1, the semiconductor light emitting element 10 sequentially includes, along the X-axis from a semiconductor substrate 1, an n-cladding layer 2, an active layer 3, a photonic crystal layer 4, a p-cladding layer 5, a contact layer 6, and an electrode 9. In the following description, the origin of the XYZ orthogonal coordinate system is set in the semiconductor substrate 1, the direction in which the n-cladding layer 2 is provided on the semiconductor substrate 1 is the X-axis positive direction, the right direction on the surface of FIG. 1 is the Y-axis positive direction, and the depth direction of the surface of FIG. 1 is the Z-axis positive direction. The X-axis negative direction side of the semiconductor substrate 1 is provided with an antireflection film 7 and an electrode 8. The conductivity type between the active layer 3 and the electrode 8 is n-type, and the conductivity type between the active layer 3 and the electrode 9 is p-type. The semiconductor substrate 1, the n-cladding layer 2, the active layer 3, the photonic crystal layer 4, the p-cladding layer 5, the contact layer 6, and the electrode 9 are arranged on the X-axis. The semiconductor substrate 1, the n-cladding layer 2, the active layer 3, the photonic crystal layer 4, the p-cladding layer 5, and the contact layer 6 serve as a semiconductor unit of group III-V compound semiconductors. The semiconductor unit is provided between the electrode 8 and the electrode 9. The electrode 8, the active layer 3, the photonic crystal layer 4, and the electrode 9 are stacked along the X-axis serving as the reference axis.

The semiconductor substrate 1 is cuboid. The material of the semiconductor substrate 1 is, for example, GaAs. The thickness of the semiconductor substrate 1 is, for example, from 80 μm to 350 μm.

The n-cladding layer 2 is formed on the X-axis positive direction side of the semiconductor substrate 1. The material of the n-cladding layer 2 is, for example, AlGaAs. The thickness of the n-cladding layer 2 is, for example, from 1.0 μm to 3.0 μm.

The active layer 3 supplies light to the photonic crystal layer 4. The active layer 3 is positioned between the n-cladding layer 2 and the photonic crystal layer 4. The active layer 3 includes, for example, a quantum well layer. The active layer 3 has a laminated structure of AlGaAs and InGaAs. The thickness of the active layer 3 is, for example, from 10 nm to 100 nm.

The photonic crystal layer 4 is provided to stabilize oscillations. The photonic crystal layer 4 generates a laser beam by optical resonance. The photonic crystal layer 4 determines the wavelength of the resonating laser beam. The photonic crystal layer 4 is positioned between the active layer 3 and the p-cladding layer 5. The materials of the photonic crystal layer 4 are, for example, GaAs and AlGaAs. The thickness of the photonic crystal layer 4 is, for example, from 100 nm to 400 nm. For example, the photonic crystal layer 4 is formed as follows: a basic layer 4a made of GaAs is provided with a plurality of holes at regular intervals; and then buried layers 4b made of AlGaAs are grown in the holes. Note that the same material as that of the p-cladding layer 5 can be buried in crystal patterns of the photonic crystal layer 4, or a structure in which air is retained can be used as the crystal patterns of the photonic crystal layer 4.

The p-cladding layer 5 is provided on the X-axis positive direction side of the photonic crystal layer 4. The material of the p-cladding layer 5 is, for example, AlGaAs of p-type. The thickness of the p-cladding layer 5 is, for example, from 1.0 μm to 3.0 μm.

The contact layer 6 is provided on the X-axis positive direction side of the p-cladding layer 5. The material of the contact layer 6 is, for example, GaAs. The thickness of the contact layer 6 is, for example, from 50 nm to 500 nm. An insulating layer F of, for example, SiO₂ or SiNₓ is provided as necessary on the contact layer 6.

The antireflection film 7 is provided on the X-axis negative direction side of the semiconductor substrate 1. The material of the antireflection film 7 is, for example, SiN.

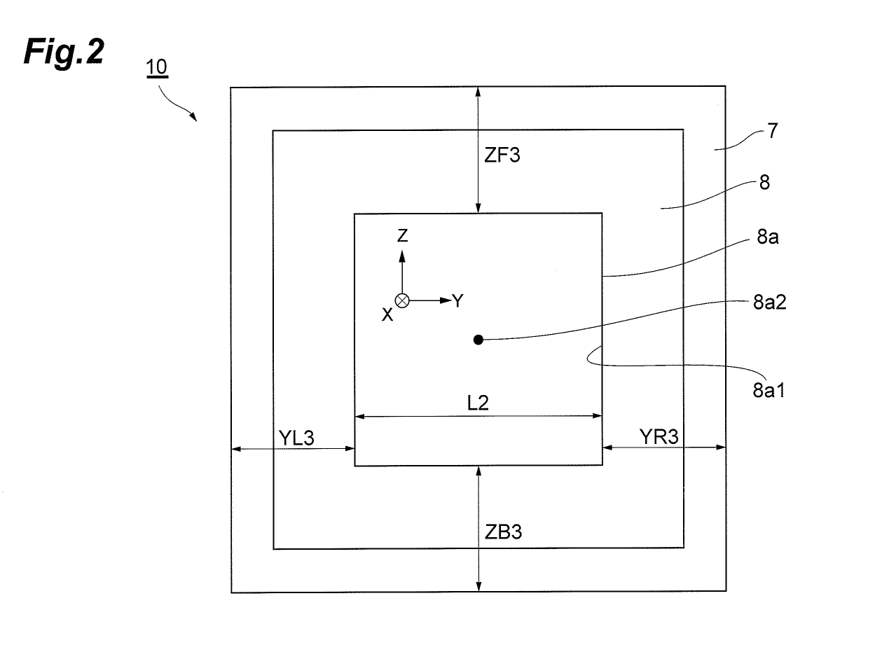

The electrode 8 is provided on the X-axis negative direction side of the semiconductor substrate 1. The electrode 8 is provided at a part at which the antireflection film 7 does not exist. The shape of the electrode 8 is, for example, substantially cuboid. The electrode 8 has, for example, a square face, as illustrated in FIG. 2. The distance from the electrode 8 to the active layer 3 is, for example, 100 μm. Examples of the materials that can be used in the electrode 8 include metals, such as Au, Ge, and Ni, and alloys thereof.

The electrode 8 has an opening 8a. The opening 8a is positioned on the X-axis. The shape of the opening 8a is square. The length of a side of the opening 8a is L2. For example, when the distance between an end on the Z-axis positive direction side of the semiconductor light emitting element 10 and an end on the Z-axis positive direction side of the opening 8a is ZF3; the distance between an end on the Z-axis negative direction side of the semiconductor light emitting element 10 and an end on the Z-axis negative direction side of the opening 8a is ZB3; the distance between an end on the Y-axis negative direction side of the semiconductor light emitting element 10 and an end on the Y-axis negative direction side of the opening 8a is YL3; and the distance between an end on the Y-axis positive direction side of the semiconductor light emitting element 10 and an end on the Y-axis positive direction side of the opening 8a is YR3, it holds that ZF3=ZB3=YL3=YR3. The laser beam LA is emitted from the opening 8a out of the semiconductor light emitting element 10. When viewed from the X-axis, the opening 8a has an end 8e1 (third end) positioned in the Y-axis negative direction (first direction), and an end 8e2 (fourth end) positioned in the Y-axis positive direction (second direction) that is the direction opposite to the Y-axis negative direction. The planar shapes of the electrode 8 and the opening 8a need not be square, but may be shaped otherwise, such as rectangular, circular, or hexagonal. The electrode 8 has a central part 8a2. All distances from the central part 8a2 to respective sides of the electrode 8 are substantially the same.

The electrode 9 is provided on the X-axis positive direction side of the contact layer 6. The shape of the electrode 9 is, for example, substantially cuboid. The electrode 9 is provided in an opening formed at the insulating layer F. Examples of the materials that can be used in the electrode 9 include metals, such as Au, Cr, and Ti, in the same manner as in the case of the electrode 8.

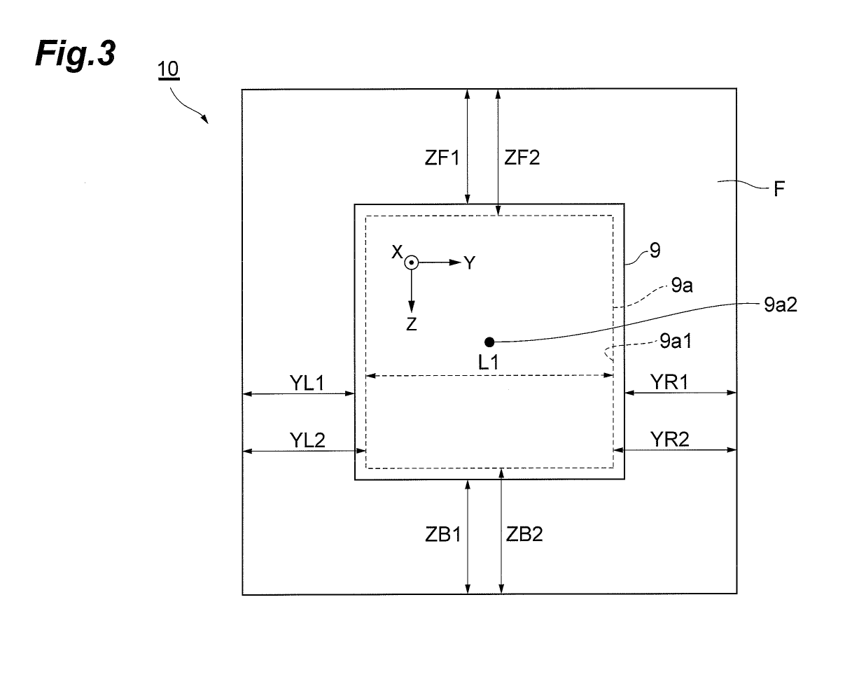

For example, as illustrated in FIG. 3, when the distance between the end on the Z-axis negative direction side of the semiconductor light emitting element 10 and an end on the Z-axis negative direction side of the electrode 9 is ZF1; the distance between the end on the Z-axis positive direction side of the semiconductor light emitting element 10 and an end on the Z-axis positive direction side of the electrode 9 is ZB1; the distance between the end on the Y-axis positive direction side of the semiconductor light emitting element 10 and an end on the Y-axis positive direction side of the electrode 9 is YR1; and the distance between the end on the Y-axis negative direction side of the semiconductor light emitting element 10 and an end on the Y-axis negative direction side of the electrode 9 is YL1, it holds that ZF1=ZB1=YR1=YL1.

The electrode 9 has a contact surface 9a on the X-axis negative direction side of the electrode 9. The contact surface 9a is a surface contacting with the contact layer 6. The shape of the contact surface 9a is square. The length of a side of the contact surface 9a is L1. For example, when the distance between the end on the Z-axis negative direction side of the semiconductor light emitting element 10 and an end on the Z-axis negative direction side of the contact surface 9a is ZF2; the distance between the end on the Z-axis positive direction side of the semiconductor light emitting element 10 and an end on the Z-axis positive direction side of the contact surface 9a is ZB2; the distance between the end on the Y-axis positive direction side of the semiconductor light emitting element 10 and an end on the Y-axis positive direction side of the contact surface 9a is YR2; and the distance between the end on the Y-axis negative direction side of the semiconductor light emitting element 10 and an end on the Y-axis negative direction side of the contact surface 9a is YL2, it holds that ZF2=ZB2=YR2=YL2. When viewed from the axis line direction of the X-axis, the electrode 9 has an end 9e1 (first end) positioned in the Y-axis negative direction, and an end 9e2 (second end) positioned in the Y-axis positive direction. The electrode 9 has a central part 9a2. All distances from the central part 9a2 to respective sides of the electrode 9 are substantially the same.

As illustrated in FIG. 1, the distance from the electrode 9 to the active layer 3 is much smaller than the distance from the electrode 8 to the active layer 3, and, for example, several micrometers. Hence, the range of a power supply injected into the active layer 3 corresponds to the contact surface 9a. The shape of the contact surface 9a need not be square, but may be any shape that is the same as that of the opening 8a. The X-axis passes through the central part 8a2 of the opening 8a in the YZ-plane (refer to FIG. 2) that is orthogonal to the direction in which the electrode 8, the active layer 3, the photonic crystal layer 4, and the electrode 9 are stacked.

An operation of the semiconductor light emitting element 10 configured as described above will briefly be described. When a drive voltage is applied and a current is passed between the electrode 8 and the electrode 9, carriers concentrate in the active layer 3. In an area where the carriers concentrate, electrons and holes recombine, and emission of light occurs. In the emission of light, resonance is created in core layers from the n-cladding layer 2 to the p-cladding layer 5 by the photonic crystal layer 4, and the laser beam LA is generated. The laser beam LA is emitted from the opening 8a out of the semiconductor light emitting element 10.

It has been found that, when the photonic crystals are used in a conventional semiconductor light emitting element, a very weak noise pattern exists at the periphery of the laser beam emitted in the X-axis direction (for example, refer to Non Patent Literature 1). This noise pattern is generated because the light in an oscillating state is subjected to inelastic scattering due to, for example, disturbance in the photonic crystals, and is diffracted by the photonic crystals. Regarding the semiconductor light emitting element in which the noise pattern is generated, it has been found that the noise light corresponding to the noise pattern leaks out of the current injection area, that is, into an area in which the emission of light does not occur. The noise light is a problem because, if, for example, an optical interconnection is formed on multiple channels, the optical interconnection can cause crosstalk to adjacent channels.

Hence, in the semiconductor light emitting element 10 according to the present embodiment, an outer circumference 8a1 of the opening 8a of the electrode 8 and an outer circumference 9a1 of the contact surface 9a of the electrode 9 substantially coincide with each other in the YZ-plane orthogonal to the X-axis. For example, when δL is a positive real number much smaller than the length L1 of the side of the contact surface 9a and the length L2 of the side of the opening 8a, it holds that L2=L1±δL.

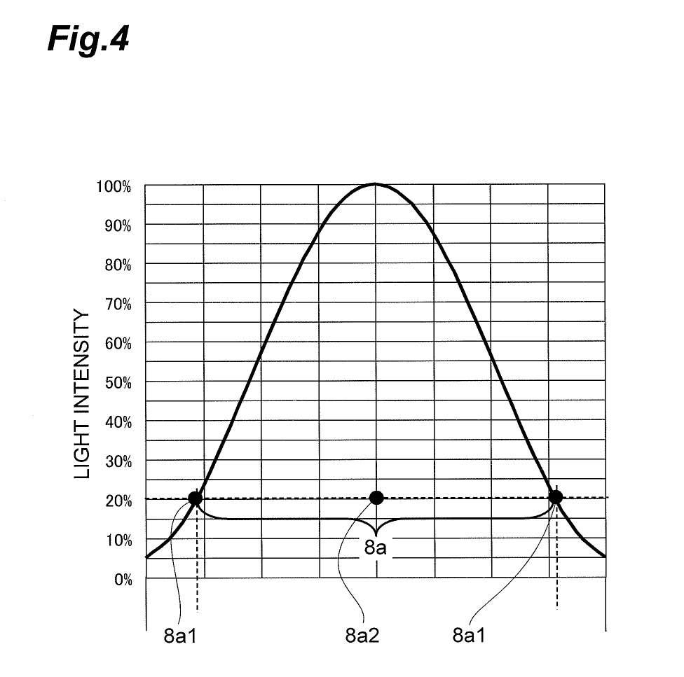

The value of δL can be represented by an absolute value, for example, several micrometers, or can be represented by a relative value, for example, 1% of the length L2 of the side of the opening 8a. For example, as illustrated in the graph of FIG. 4, if, in the intensity distribution of light reaching the opening 8a, the intensity is maximum at the central part 8a2 of the opening 8a and decreases as a position is farther from the central part 8a2 toward the outer circumference 8a1 in the YZ-plane, the portions in which the intensity of light is a reference value (such as 20% of the maximum value) or less can be set as δL. In this manner, the value of δL is set so that the noise light is not emitted from the opening 8a.

As described above, the end 9e1 of the electrode 9 and the end 8e1 of the opening 8a substantially coincide with each other when viewed from the axis line direction of the X-axis, as illustrated in FIG. 1. As a result, the noise light existing at the outer circumference 9a1 of the electrode 9 is blocked at a part positioned outside the opening 8a of the electrode 8. Hence, the above-described problem is solved because the noise light is not emitted from the opening 8a.

The minimum value of the intensity of the light that is output from the active layer 3 and the photonic crystal layer 4 and reaches the opening 8a is not less than A % (satisfying 10≦A≦30) of the maximum value of the intensity of the light that is output from the active layer 3 and the photonic crystal layer 4 and reaches the opening 8a. If the intensity of the light reaching the opening 8a is distributed as illustrated in the graph of FIG. 4, the intensity of light reaching the outer circumference 8a1 is not less than 20% of the intensity of light reaching the central part 8a2. In this manner, by making the minimum value of the intensity of the light reaching the opening 8a, for example, 20% or more, the weak noise light existing at the outer circumference 8a1 of the opening 8a is prevented from passing through the opening 8a. Hence, the emission of the noise light out of the semiconductor light emitting element 10 can be reduced.

The transmission light intensity of the electrode 8 decreases as a distance from the outer circumference of the opening 8a increases. The transmission light intensity of the electrode 8 is continuously reduced by, for example, an absorptive neutral density (ND) filter. Specifically, when the electrode 8 is formed, transmittance is reduced as a distance from the outer circumference 8a1 of the opening 8a increases, for example, by continuously changing the density of thin films of the ND filter at the outer circumference 8a1 of the opening 8a. In this manner, the emission of the noise light at the outer circumference 8a1 of the opening 8a can be reduced by reducing the transmittance as a distance from the outer circumference 8a1 of the opening 8a increases. The transmittance can be changed, not continuously, but, for example, in a stepwise manner. A reflective ND filter can be used instead of the absorptive ND filter. Examples of usable reflective ND filters include a filter produced by vapor-depositing metal thin films of, for example, chromium so that the density varies, and a filter formed by applying vapor deposition to the opening of the electrode 9 so that the density varies.

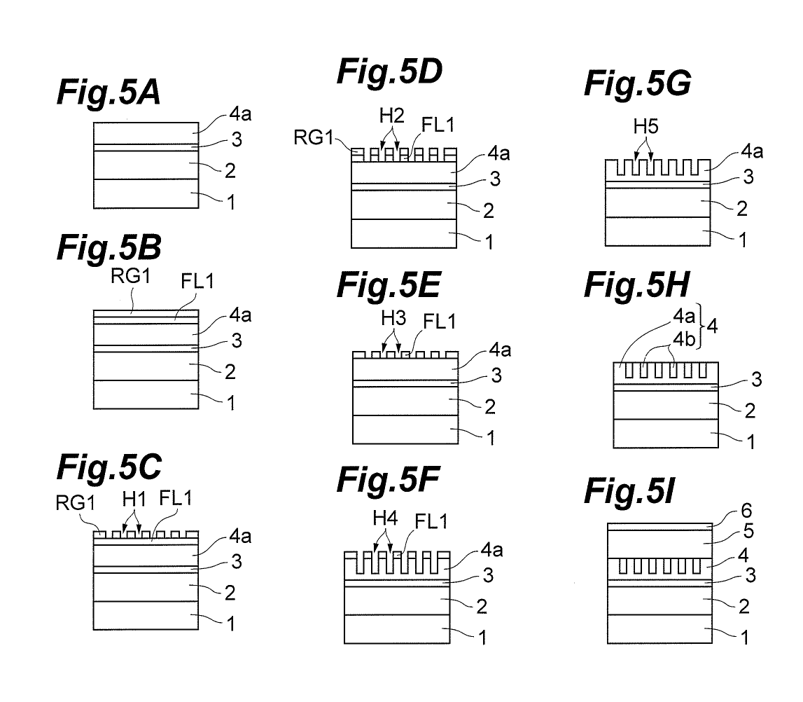

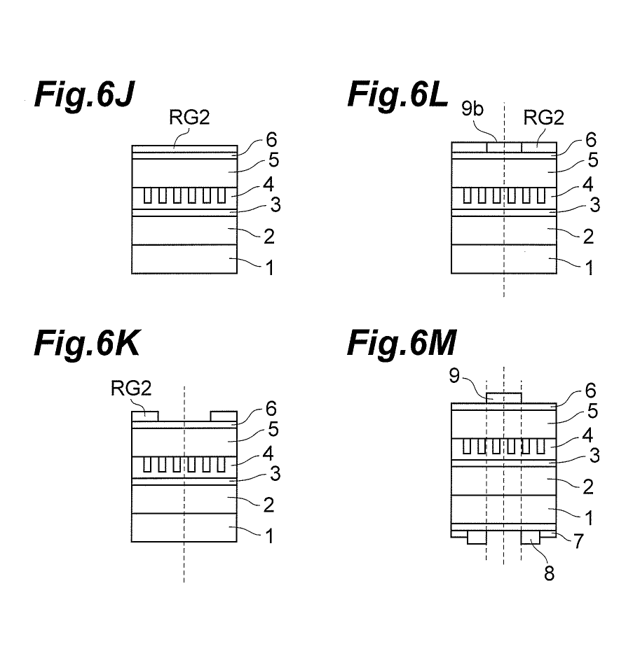

A description will be made of an example of a method of manufacturing the semiconductor light emitting element 10 of the first embodiment configured as described above, with reference to FIGS. 5A to 5I and 6J to 6M. The n-cladding layer 2 made of AlGaAs, the active layer 3 having the laminated structure of AlGaAs and InGaAs, and the basic layer 4a made of GaAs are sequentially epitaxially grown on the semiconductor substrate 1 made of GaAs (FIG. 5A) by the metal organic chemical vapor deposition (MOCVD) or other techniques.

Then, a mask layer FL1 made of SiN is formed on the basic layer 4a using plasma-enhanced chemical vapor deposition (PCVD), and a resist RG1 is applied onto the mask layer FL1 (FIG. 5B). Two-dimensional micropatterns are drawn using an electron beam drawing device, and are developed so as to form two-dimensional (or one-dimensional) micropatterns (corresponding to positions of the buried layers 4b) in the resist RG1 (FIG. 5C). Hereby, a plurality of holes H1 serving as the micropatterns are formed in the resist RG1. The holes H1 reach a surface of the mask layer FL1.

Then, the mask layer FL1 is etched using the resist RG1 as a mask, and thus the micropatterns of the resist are transferred to the mask layer FL1 (FIG. 5D). Reactive ion etching (RIE) can be used as this etching. A fluorine-based gas (CF₄, CHF₃, or C₂F₆) can be used as an etching gas for SiN. Holes H2 are formed in the mask layer FL1 by this etching. The holes H2 reach a surface of the basic layer 4a.

Then, the resist RG1 is immersed in a stripping solution. Further, the resist RG1 is ashed so that the resist RG1 is removed (FIG. 5E). Photoexcitation ashing or plasma ashing can be used as the ashing. Hereby, only the mask layer FL1 having a plurality of holes H3 remains on the basic layer 4a.

Using the mask layer FL1 as a mask, the basic layer 4a is etched, and thus the micropatterns of the mask layer FL1 are transferred to the basic layer 4a (FIG. 5F). Dry etching is used as this etching. In the dry etching, a chlorine-based or fluorine-based gas can be used as an etching gas. Examples of usable etching gases include a main etching gas, such as Cl₂, SiCl₄, or SF₆, mixed with, for example, Ar gas. The depth of the holes H4 formed in the basic layer 4a is, for example, approximately 100 nm. The depth of the holes H4 is smaller than the thickness of the basic layer 4a. The holes H4 can reach a surface of a semiconductor layer serving as a base for the basic layer 4a.

Then, only the mask layer FL1 made of SiN is removed by the reactive ion etching (RIB), and thus open end faces of holes H5 continuing to the holes H4 are exposed. In other words, the surface of the basic layer 4a is exposed (FIG. 5G). As described above, a fluorine-based gas (CF₄, CHF₃, or C₂F₆) can be employed as an etching gas for SiN. Thereafter, surface treatment, such as surface cleaning including thermal cleaning of the basic layer 4a, is performed.

Then, using the MOCVD, the buried layers 4b are formed (regrown) in the holes H5 (FIG. 5H). In this regrowth process, AlGaAs is supplied onto the surface of the basic layer 4a. AlGaAs supplied has a higher composition ratio of Al than that of the basic layer 4a. At an initial stage of the regrowth, AlGaAs fills in the holes H5, and forms the buried layers 4b. When the holes H5 have been filled, AlGaAs supplied thereafter is stacked as a buffer layer on the basic layer 4a. Thereafter, by using the MOCVD, the p-cladding layer 5 made of AlGaAs and the contact layer 6 made of GaAs are sequentially grown on the photonic crystal layer 4 (FIG. 5I). A composition ratio X of Al in the p-cladding layer 5 is more than or equal to the composition ratio X of Al in the buried layers 4b, and can be set so that, for example, X=0.4. The above-described crystal growths are all epitaxial growths, and crystal orientations of the respective semiconductor layers are the same.

Then, a resist RG2 is applied onto the contact layer 6 (FIG. 6J). Thereafter, an opening pattern for placing the electrode 9 is formed at the resist RG2 (FIG. 6K). Using the resist RG2 having the opening pattern as a mask, an electrode material 9b is deposited on the resist RG2 and an exposed surface of the contact layer 6 (FIG. 6L). For example, vapor deposition or sputtering can be used for formation of the electrode material 9b. Thereafter, the resist RG2 is removed by liftoff to leave the square electrode material 9b on the contact layer 6, and thus the electrode 9 is formed.

Mirror polishing, for example, is applied to the surface on the X-axis negative direction side of the semiconductor substrate 1, and thereafter, the antireflection film 7 made of, for example, SiN is formed on the same surface using, for example, the PCVD. The antireflection film 7 is removed from only a portion of the shape of the electrode 8 using, for example, photolithography, and the electrode 8 is formed using further photolithography and vacuum vapor deposition (FIG. 6M). As described above, the electrodes 8 and 9 are formed, and thus the semiconductor light emitting element 10 is completed. When the electrodes 8 and 9 are formed, the dimensions of the contact surface 9a of the electrode 9 are set to agree with the dimensions of the opening 8a of the electrode 8.

### Second Embodiment

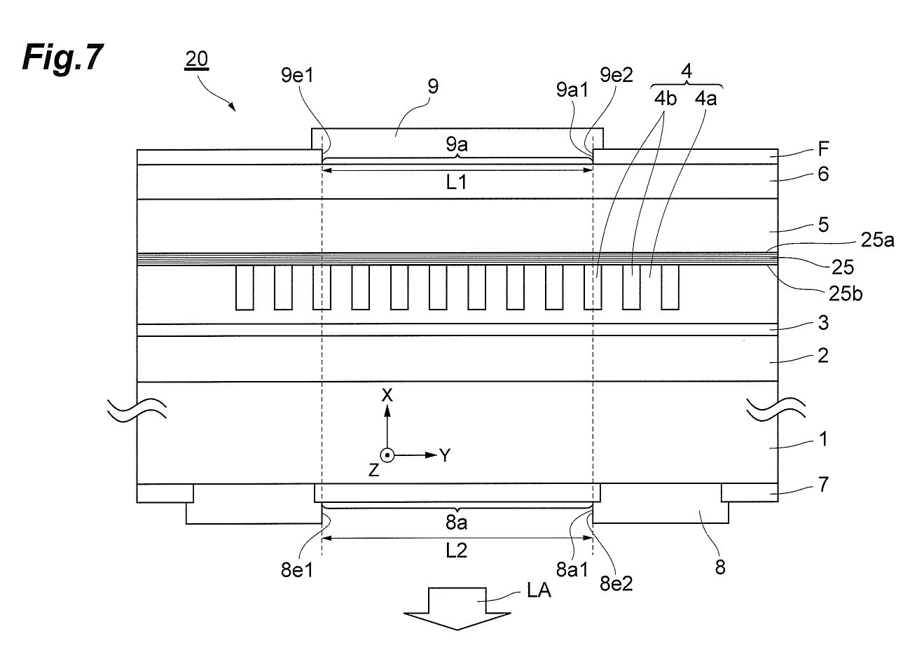

The following describes a semiconductor light emitting element 20 according to a second embodiment of the present invention, with reference to FIGS. 7, 8, and 9A to 9E. A point in which the semiconductor light emitting element 20 of the second embodiment differs from the semiconductor light emitting element 10 of the first embodiment is that a p-type distributed Bragg reflector (DBR) layer 25 is provided between the photonic crystal layer 4 and the p-cladding layer 5, as illustrated in FIG. 7.

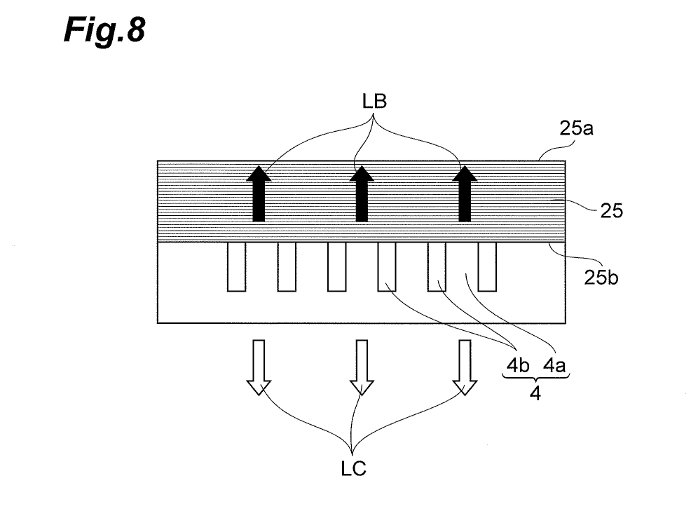

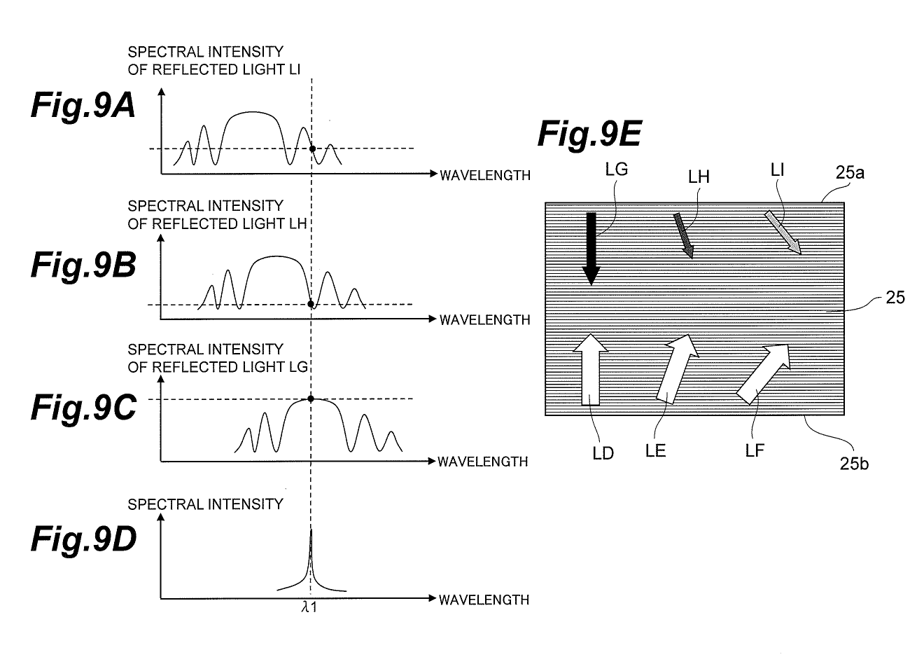

The DBR layer 25 is provided on the X-axis. A surface 25a on the X-axis positive direction side of the DBR layer 25 and a surface 25b on the X-axis negative direction side of the DBR layer 25 contact with the p-cladding layer 5 and the photonic crystal layer 4, respectively. The DBR layer 25 reflects a laser beam LB generated by the photonic crystal layer 4, and emits a reflected light LC to the photonic crystal layer 4, for example, as illustrated in FIG. 8. The DBR layer 25 is also called a mirror layer. The DBR layer 25 has a multilayer semiconductor structure in which, for example, AlGaAs layers having different Al composition ratios are alternately stacked. The DBR layer 25 converts the intensity of the reflected light according to the angle of incidence of incident light. For example, there are incident light LD incoming in the X-axis direction and incident light LE and LF each incoming at an angle with the X-axis as illustrated in FIG. 9E, the DBR layer 25 has a function to reduce the intensities of reflected light LH of the incident light LE and reflected light LI of the incident light LF to below the intensity of reflected light LG of the incident light LD. For example, when there are reflection characteristics of the reflected light LG, LH, and LI as illustrated in FIGS. 9A to 9C, a wavelength λ1 is determined by the DBR layer 25 so that the intensity of the reflected light LG is higher than those of the reflected light LH and LI (FIG. 9D).

A method of manufacturing the semiconductor light emitting element 20 of the second embodiment differs from the method of manufacturing the semiconductor light emitting element 10 of the first embodiment only in the process of growing the p-cladding layer 5 and the contact layer 6 on the photonic crystal layer 4 (FIG. 5I). Specifically, the DBR layer 25, the p-cladding layer 5, and the contact layer 6 are sequentially grown on the photonic crystal layer 4. Processes thereafter (processes of FIG. 6J and later) are the same as those of the method of manufacturing the semiconductor light emitting element 10 of the first embodiment.

As described above, in the semiconductor light emitting element 20 of the second embodiment, the reflection intensity of light can be varied by the DBR layer 25 between the X-axis direction and other directions, and thus the reflected light emitted in directions other than the X-axis direction can be reduced in intensity to a level below that of the reflected light emitted in the X-axis direction. Hence, the noise light emitted in directions other than the X-axis direction can be reduced. Instead of the DBR layer 25, a single-layer metal reflection film of, for example, Al, Au, or Ag can be used as the mirror layer.

### Third Embodiment

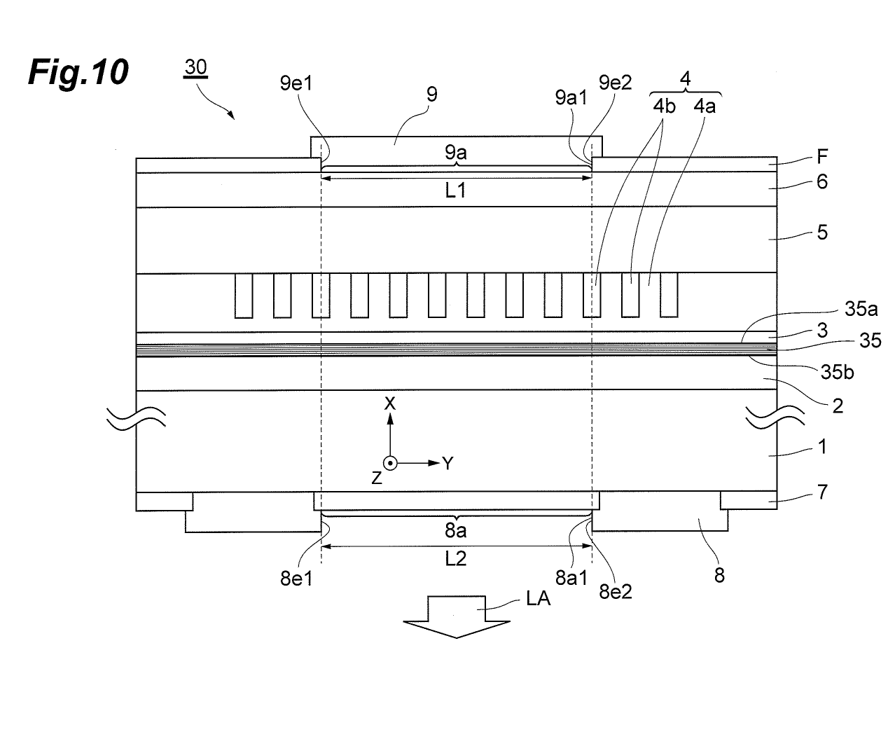

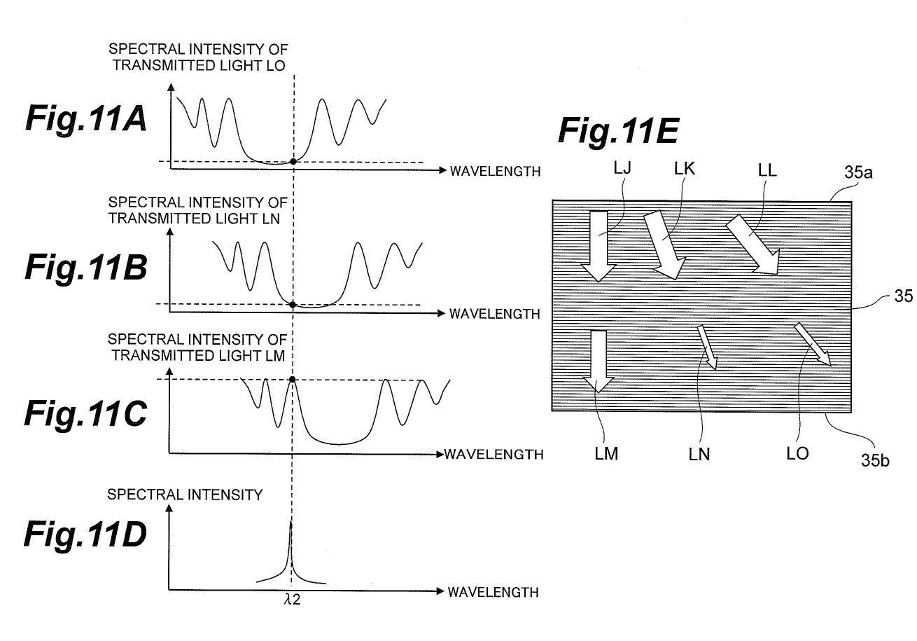

The following describes a semiconductor light emitting element 30 according to a third embodiment of the present invention, with reference to FIGS. 10 and 11A to 11E. A point in which the semiconductor light emitting element 30 of the third embodiment differs from the semiconductor light emitting element 10 of the first embodiment is that a DBR layer 35 is provided between the n-cladding layer 2 and the active layer 3, as illustrated in FIG. 10.

The DBR layer 35 is provided on the X-axis. A surface 35a on the X-axis positive direction side of the DBR layer 35 and a surface 35b on the X-axis negative direction side of the DBR layer 35 contact with the active layer 3 and the n-cladding layer 2, respectively. The DBR layer 35 has a function of transmitting the laser beam generated by the photonic crystal layer 4. In the same manner as in the case of the DBR layer 25, the DBR layer 35 has a multilayer semiconductor structure in which, for example, AlGaAs layers having different Al composition ratios are alternately stacked. The DBR layer 35 converts the intensity of the transmitted light according to the angle of incidence of incident light. For example, in the case where there are incident light LJ incoming in the X-axis direction, and incident light LK and LL each incoming at an angle with the X-axis as illustrated in FIG. 11E, the DBR layer 35 has a function to reduce the intensities of transmitted light LN of the incident light LK and transmitted light LO of the incident light LL to below the intensity of transmitted light LM of incident light A. When there are transmission characteristics of the transmitted light LM, LN, and LO as illustrated in FIGS. 11A to 11C, a wavelength λ2 is determined by the DBR layer 35 so that the intensity of the transmitted light LM is higher than those of the transmitted light LN and LO (FIG. 11D).

A method of manufacturing the semiconductor light emitting element 30 of the third embodiment differs from the method of manufacturing the semiconductor light emitting element 10 of the first embodiment only in the process of growing the n-cladding layer 2, the active layer 3, and the basic layer 4a on the semiconductor substrate 1 (FIG. 5A). Specifically, the n-cladding layer 2, the DBR layer 35, the active layer 3, and the basic layer 4a are sequentially epitaxially grown on the semiconductor substrate 1 by the metal organic chemical vapor deposition (MOCVD) or other techniques. Processes thereafter (processes of FIG. 5B and later) are the same as those of the method of manufacturing the semiconductor light emitting element 10 of the first embodiment.

As described above, in the semiconductor light emitting element 30 of the third embodiment, the transmission light intensity can be varied by the DBR layer 35 between the X-axis direction and other directions, and thus the transmitted light emitted in directions other than the X-axis direction can be reduced in intensity to a level below that of the transmitted light emitted in the X-axis direction. Hence, the noise light emitted in directions other than the X-axis direction can be reduced in the same manner as in the case of the semiconductor light emitting element 20 of the second embodiment.

The second embodiment and the third embodiment include either the DBR layer 25 or the DBR layer 35, and consequently can vary the intensity of emitted light between the X-axis direction and other directions. Hence, the noise light emitted in directions other than the reference axis direction can be reduced. The configuration can be such that a DBR layer is provided in either of positions between the electrode 8 and the photonic crystal layer 4, and between the electrode 9 and the photonic crystal layer 4. Furthermore, the configuration can be such that DBR layers are provided in both positions between the electrode 8 and the photonic crystal layer 4, and between the electrode 9 and the photonic crystal layer 4.

The above are examples of embodiments of the present invention. Consequently, the configuration can be such that, for example, the photonic crystal layer 4 is provided in either of positions between the active layer 3 and the electrode 8 and between the active layer 3 and the electrode 9. The configuration of materials, film thicknesses, and layers can be changed as appropriate, provided that the configuration includes the active layer 3, the photonic crystal layer 4, and the electrodes 8 and 9.

### INDUSTRIAL APPLICABILITY

With the semiconductor light emitting element 10, 20, or 30, the optical output can sufficiently be obtained, and the emission of the noise light caused by the photonic crystals can be reduced.

### REFERENCE SIGNS LIST

1 . . . semiconductor substrate, 2 . . . n-cladding layer, 3 . . . active layer, 4 . . . photonic crystal layer, 5 . . . p-cladding layer, 6 . . . contact layer, 7 . . . antireflection film, 8 . . . electrode (first electrode), 8a . . . opening, 8a1 . . . outer circumference, 8a2 . . . central part (central part of opening), 8e1 . . . end (third end), 8e2 . . . end (fourth end), 9 . . . electrode (second electrode), 9a . . . contact part, 9a1 . . . outer circumference, 9a2 . . . central part, 9e1 . . . end (first end), 9e2 . . . end (second end), 10, 20, 30 . . . semiconductor light emitting element, 25, 35 . . . DBR layer, F . . . insulating layer.

1. A semiconductor light emitting element comprising:
a first electrode;
a semiconductor unit of group III-V compound semiconductors; and
a second electrode, wherein
the semiconductor unit is provided between the first electrode and the second electrode,
the semiconductor unit comprises an active layer and a photonic crystal layer,
the photonic crystal layer is provided in either of positions between the active layer and the first electrode, and between the active layer and the second electrode,
conductivity types between the active layer and the first electrode and between the active layer and the second electrode differ from each other,
the first electrode is provided with an opening,
the first electrode, the active layer, the photonic crystal layer, and the second electrode are stacked along a reference axis,
the reference axis passes through a central part of the opening when viewed from an axis line direction of the reference axis,
the second electrode comprises a first end positioned in a first direction when viewed from the axis line direction of the reference axis, and a second end positioned in a second direction that is a direction opposite to the first direction,
the opening has a third end positioned in the first direction when viewed from the axis line direction of the reference axis, and a fourth end positioned in the second direction, and
the first end of the second electrode and the third end of the opening substantially coincide with each other when viewed from the axis line direction of the reference axis.

2. A semiconductor light emitting element comprising:
a first electrode;
a semiconductor unit of group III-V compound semiconductors: and
a second electrode, wherein
the semiconductor unit is provided between the first electrode and the second electrode,
the semiconductor unit comprises an active layer and a photonic crystal layer,
the photonic crystal layer is provided in either of positions between the active layer and the first electrode, and between the active layer and the second electrode,
conductivity types between the active layer and the first electrode and between the active layer and the second electrode differ from each other,
the first electrode is provided with an opening, and
a minimum value of an intensity of light that is output from the active layer and the photonic crystal layer and reaches the opening is not less than A % (satisfying 10≦A≦30) of a maximum value of the intensity of the light that is output from the active layer and the photonic crystal layer and reaches the opening.

3. The semiconductor light emitting element according to claim 1, wherein a transmission light intensity of the first electrode decreases as a distance from the outer circumference of the opening increases.

4. The semiconductor light emitting element according to claim 1, further comprising a distributed Bragg reflector (DBR) layer, wherein
the DBR layer is provided in either of positions between the first electrode and the photonic crystal layer, and between the second electrode and the photonic crystal layer.

5. The semiconductor light emitting element according to claim 1, further comprising a first DBR layer and a second DBR layer, wherein
the first DBR layer is provided between the first electrode and the photonic crystal layer, and
the second DBR layer is provided between the second electrode and the photonic crystal layer.
